(19) United States
(12) Patent Application Publication
(10) Pub. No.: US 2026/0367536 A1
(43) Pub. Date: Nov. 19, 2026

(54) Dust Management for a Gas Discharge Chamber

(71) Applicant: Cymer, LLC, San Diego, CA (US)

(72) Inventors: Zhou Wang, San Diego, CA (US); Shuang Xu, San Diego, CA (US); Stephen Michael Ubnoske, San Diego, CA (US); Thomas Dickson Steiger, San Diego, CA (US); Thomas Patrick Duffey, San Diego, CA (US); Rostislav Rokitski, San Diego, CA (US)

(21) Appl. No.: 19/158,664

(22) PCT Filed: Mar. 7, 2024
(86) PCT No.: PCT/IB2024/052180

§ 371 Date: Aug. 21, 2025

Related U.S. Application Data
(60) Provisional application No. 63/488,821, filed on Mar. 7, 2023.
(60) Provisional application No. 63/627,854, filed on Feb. 1, 2024.

(51) Int. Cl. G03F 7/00; H01S 3/036

(52) U.S. Cl. CPC G03F 7/70916; G03F 7/70016; H01S 3/036

(57) ABSTRACT

A dust collector for a gas discharge chamber of a light source includes: an inlet port, an outlet port, and a passive dust trap. The inlet port fluidly communicates with a cavity of the gas discharge chamber. The outlet port fluidly communicates with an active dust trap such that an outflow path external to the cavity of the gas discharge chamber is defined from the inlet port to the outlet port along an outflow direction. The passive dust trap extends across the outflow path and is configured to define a second flow path that extends at least partly along a second direction different from the outflow direction and to a collection pocket defined in a collector body of the passive dust trap.

### CROSS-REFERENCE TO RELATED APPLICATIONS

This application claims priority of U.S. application 63/488,821 which was filed on Mar. 7, 2023 and U.S. application 63/627,854 which was filed on Feb. 1, 2024 which are incorporated herein in its entirety by reference.

### TECHNICAL FIELD

The disclosed subject matter relates to dust management for a gas discharge chamber of a light source.

### BACKGROUND

One kind of gas discharge light source used in photolithography is termed an excimer light source or laser. Typically, an excimer laser uses a combination of one or more noble gases, which can include argon, krypton, or xenon, and a reactive gas, which can include fluorine or chlorine as the gain medium. The excimer laser can create an excimer (or exciplex), a pseudo-molecule, under appropriate conditions of electrical simulation (energy supplied) and high pressure (of the gas mixture), the excimer only existing in an energized state. The excimer in an energized state gives rise to amplified light in the ultraviolet range. An excimer light source can use a single gas discharge chamber or multiple gas discharge chambers. When the excimer light source is performing, the excimer light source produces a deep ultraviolet (DUV) light beam. DUV light can include wavelengths from, for example, about 100 nanometers (nm) to about 280 nm. The energy can be supplied to the gain medium by way of electrodes, which can erode during operation and create metal fluoride (or metal chloride) dust particles.

The DUV light beam can be directed to a photolithography exposure apparatus or scanner, which is a machine that applies a desired pattern onto a target portion of a substrate (such as a silicon wafer). The DUV light beam interacts with a projection optical system, which projects the DUV light beam through a mask onto the photoresist of the wafer. In this way, one or more layers of chip design is patterned onto the photoresist and the wafer is subsequently etched and cleaned.

### SUMMARY

In some general aspects, a dust collector for a gas discharge chamber of a light source includes an inlet port, an outlet port, and a baffle. The inlet port fluidly communicates with a cavity of the gas discharge chamber. The outlet port fluidly communicates with an active dust trap such that an outflow path external to the cavity of the gas discharge chamber is defined from the inlet port to the outlet port along an outflow direction. The baffle extends across the outflow path and is configured to define a second flow path that extends at least partly along a second direction different from the outflow direction and to a collection pocket defined in a collector body.

In other general aspects, a dust collector for a gas discharge chamber of a light source includes an inlet port, an outlet port, and a passive dust trap. The inlet port fluidly communicates with a cavity of the gas discharge chamber. The outlet port fluidly communicates with an active dust trap such that an outflow path external to the cavity of the gas discharge chamber is defined from the inlet port to the outlet port along an outflow direction. The passive dust trap extends across the outflow path and is configured to define a second flow path that extends at least partly along a second direction different from the outflow direction and to a collection pocket defined in a collector body of the passive dust trap.

Implementations can include one or more of the following features. For example, the passive dust trap can include a baffle. The baffle can extend transversely across the outflow path. The baffle can be configured to trap dust particles within the collection pocket. The second flow path can have a constricted cross-sectional area relative to a cross-sectional area of the outflow path. The baffle can extend along an angle that is between 75°-105° or between 85°-95° relative to the outflow direction. The baffle can also define a third flow path that extends from the second flow path and toward the outflow path on the way to the active dust trap such that a bend flow path extends between the second flow path and the third flow path around the baffle. The collector body can include a protrusion that extends toward a tip of the baffle such that a constricted region of the second flow path is defined between the protrusion and the baffle near the baffle tip. The constricted region can have a cross-sectional area that is smaller than a cross-sectional area of the outflow path. The baffle can lack sharp ends and lacks sharp corners. A profile of the baffle along the flow paths is smooth. A tip of the baffle can have a curved shape that has a turn radius that is less than one inch, less than 0.5 inches, or less than 0.25 inches. The baffle can extend across the outflow path along a transverse plane and an extent of the baffle along a transverse direction can be greater than or equal to an extent of the outflow path. The baffle can be rigid. The baffle can be made of a nickel-plated metal, a bare metal, copper, brass, an alloy of nickel and copper, an alloy of copper, or Monel.

The passive dust trap can be configured to trap dust particles within the collection pocket. An interior of the collector body can define a cylindrical region and a conically-shaped region. The second flow path can form a spiraling shape that extends through the cylindrical region, the conically-shaped region, and to the collection pocket. The flow of the spiraling shape can extend from the collection pocket and back toward the outflow path along a third flow path such that a spiral flow path extends between the second flow path and the third flow path.

The collector body can be detachable from other portions of the passive dust trap. The passive dust trap can be detachable from the outflow path.

In other general aspects, a dust collector for a gas discharge chamber of a light source includes an input port, an outlet port, and a collector. The inlet port fluidly communicates with a cavity of the gas discharge chamber. The outlet port fluidly communicates with an active dust trap such that an outflow path external to the cavity of the gas discharge chamber is defined from the inlet port to the outlet port along an outflow direction. The collector is along the outflow path. The collector includes a collector body defining a second flow path extending from the outflow path to a collection pocket, the second flow path extending along a second direction that is different from the outflow direction.

Implementations can include one or more of the following features. For example, second flow path can be configured to trap dust particles within the collection pocket. The second flow path can at least partly extend along an angle that is between 75°-105° or between 85°-95° relative to the outflow direction. The collector body can further define a third flow path that extends from the second flow path around a bend and toward the outflow path on the way to the active dust trap. The second flow path can extend within a defined structure that lacks sharp ends or corners. The second flow path can be defined between a baffle extending transversely across the outflow path and a protrusion of the collector body that extends toward a tip of the baffle. The collector body can further define a third flow path that extends from the second flow path toward the outflow path and the active dust trap such that a bend flow path extends at least partly around the tip of the baffle about a turn radius that is less than one inch, less than 0.5 inches, or less than 0.25 inches.

The second flow path can have a constricted cross-sectional area relative to a cross-sectional area of the outflow path. The second flow path can extend to a cylindrical region and a conically-shaped region defined in the collector body between the outflow path and the collection pocket, and can form a cyclone that extends to the collection pocket. The flow of the cyclone can extend from the collection pocket and back toward the outflow path along a third flow path such that a cyclone flow path extends between the second flow path and the third flow path. The collector can be detachable from the outflow path.

In other general aspects, a dust management apparatus for a gas discharge chamber of a light source includes an active dust trap fluidly communicating with a cavity of the gas discharge chamber by way of an outflow path external to the cavity of the gas discharge chamber; and a dust collector along the outflow path between the active dust trap and the gas discharge chamber cavity. The dust collector includes a baffle extending across the outflow path and being configured to define a second flow path that extends at least partly along a second direction different from the outflow direction and to a collection pocket defined in a collector body.

Implementations can include one or more of the following features. For example the dust management apparatus can further include an exhaust fan within the cavity of the gas discharge chamber, the exhaust fan configured to direct dust and fluid from the cavity of the gas discharge chamber to the outflow path. A velocity of the flow of the dust and fluid through the outflow path can increase as it travels through the dust collector. The baffle can extend transversely across the outflow path. The baffle can be configured to cause dust particles to become trapped within the collection pocket. The second flow path can have a constricted cross-sectional area relative to a cross-sectional area of the outflow path. The collector body can include a protrusion that extends toward a tip of the baffle such that a constricted region of the second flow path is defined between the protrusion and the baffle near the baffle tip. The baffle can lack sharp ends or corners. A surface profile of the baffle can have a smooth shape. The baffle can extend across the outflow path along a transverse plane and an extent of the baffle along a transverse direction can be greater than or equal to an extent of the outflow path.

In other general aspects, a method of collecting dust from a cavity of a gas discharge chamber of a light source includes exhausting fluid including dust particles from the cavity into an outflow path external to the cavity toward an active dust trap; redirecting at least a portion of the fluid including the dust particles out of the outflow path and toward a second flow path that extends at least partly along a second direction that is different than a direction of the outflow path; passively compressing the redirected fluid including the dust particles to thereby increase the velocity of the redirected fluid including the dust particles; and collecting dust particles in a collection pocket while permitting the redirected fluid to return to the outflow path on the way to the active dust trap.

Implementations can include one or more of the following features. For example, fluid including dust particles can be exhausted from the cavity by operating an exhaust fan within the cavity of the gas discharge chamber, the exhaust fan configured to direct dust and fluid from the cavity of the gas discharge chamber to the outflow path. At least the portion of the fluid can be redirected out of the outflow path and toward the second flow path by blocking the fluid from directly traveling toward the active dust trap with a baffle that extends across the outflow path and defines the second flow path. The redirected fluid can be passively compressed by pushing the redirected fluid through a constricted region of the second flow path, the constricted region defined between a baffle extending across the outflow path and a protrusion of a collector body that defines the collection pocket. The velocity of the redirected fluid can be increased by increasing the velocity of the redirected fluid to be at least double the velocity of the exhausted fluid from the cavity into the outflow path.

The details of one or more implementations are set forth in the accompanying drawings and the description below. Other features will be apparent from the description and drawings, and from the claims.

### DESCRIPTION OF DRAWINGS

FIG. 1A is a block diagram of a dust collector configured to remove dust particles from a cavity of a gas discharge chamber, the dust collector positioned between the cavity and an active dust trap;

FIG. 1B is a block diagram of a close-up section showing details of the dust collector including a baffle that extends across an outflow path defined between the cavity and the active dust trap;

FIG. 1C is a close-up side cross-sectional view of the baffle of FIGS. 1A and 1B;

FIG. 2 is a perspective view of the baffle of FIGS. 1A-1C;

FIG. 3 is a perspective view of an implementation of the dust collector of FIGS. 1A and 1B, the dust collector including a collector body that includes a baffle body, and a neck body between the baffle body and the collector body;

FIG. 4A is a perspective view of the dust collector of FIG. 3, showing a cross-section 4A taken along the XZ plane;

FIG. 4B is a perspective view of the dust collector of FIG. 3, showing a cross-section 4B taken along the XY plane;

FIG. 5A is the cutaway cross-sectional view obtained from the cross-section 4A of FIG. 4A;

FIG. 5B is the cutaway cross-sectional view obtained from the cross-section 4B of FIG. 4B;

FIG. 6 is a block diagram of an implementation of a dust management apparatus configured for a cavity of a gas discharge chamber, the dust management apparatus including an active dust trap, which is an implementation of the active dust trap of FIG. 1A, and a dust collector, which is an implementation of the dust collector of FIG. 1A;

FIG. 7 is a block diagram of a implementation of a two-stage light source that includes implementations of a gas discharge chamber;

FIG. 8 is a flow chart of a procedure performed by, for example, the dust collector of FIG. 1A to collect and remove the dust particles from the cavity;

FIGS. 9A-9E show different implementations of a baffle that can be used in any of the dust collectors of FIG. 1A-7,

FIGS. 10A-10C show different implementations of a collector body of the dust collector of FIGS. 1A-7;

FIG. 11A is a block diagram of another implementation of a dust collector configured to remove dust particles from a cavity of a gas discharge chamber, the dust collector positioned between the cavity and an active dust trap;

FIG. 11B is a perspective view of the dust collector of FIG. 11A;

FIG. 12 is a perspective view of an implementation of a dust collector, the dust collector including a collector body, a main body, and a neck body between the main body and the collector body, the collector body being detachable from the rest of the dust collector; and

FIG. 13 is a perspective view of an implementation of a dust collector, the dust collector including a collector body, a main body, and a neck body between the main body and the collector body, the collector body, the main body, and the neck body being detachable from an outflow path.

### DESCRIPTION

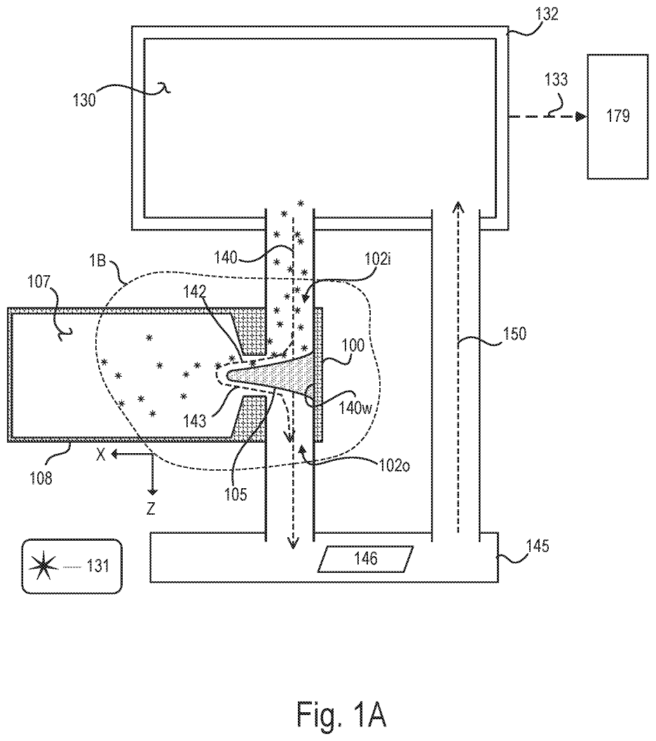

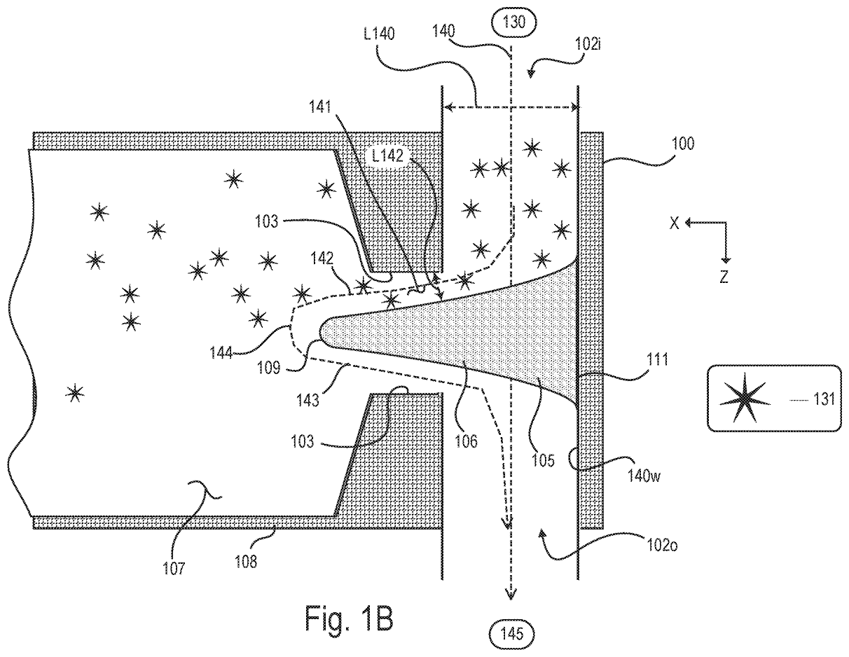

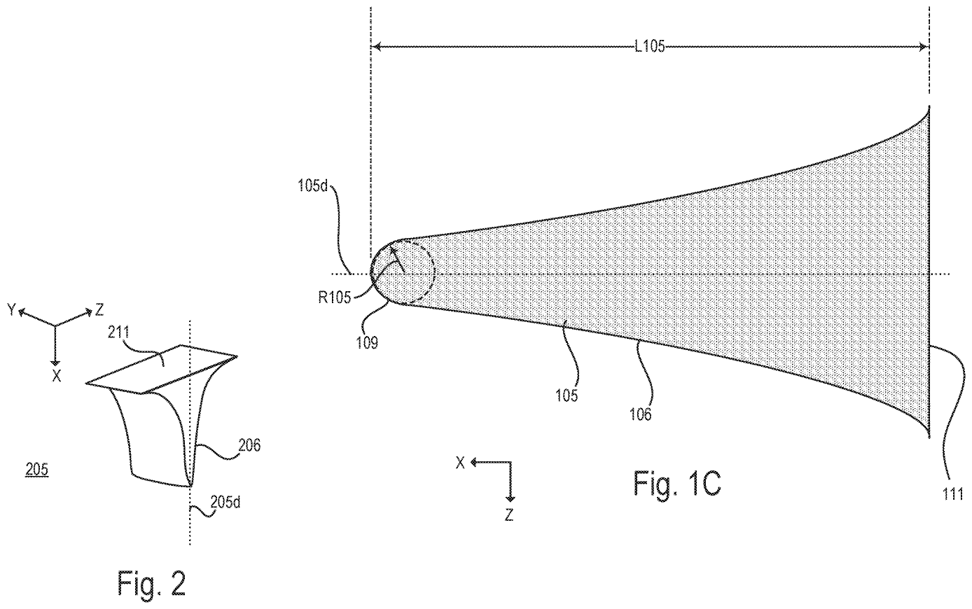

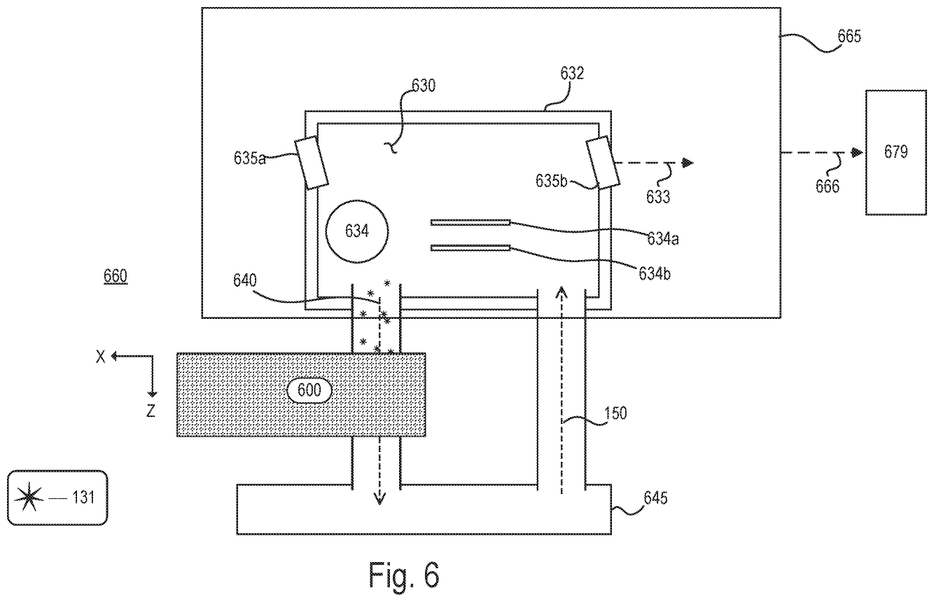

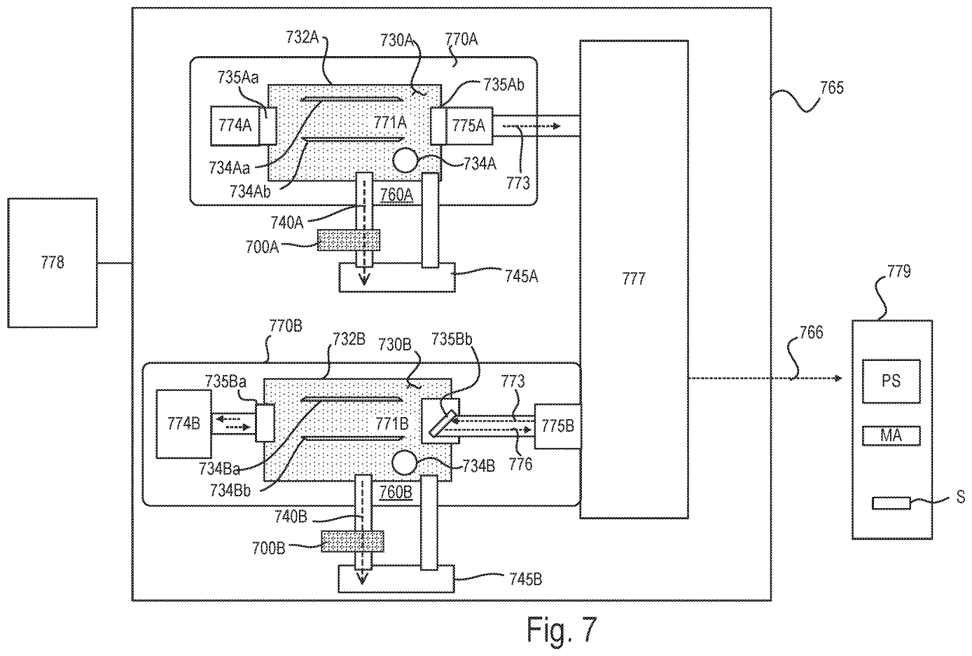

Referring to FIGS. 1A-1C, a dust collector 100 is configured for removing dust particles (or simply “dust”) 131 from a cavity 130 defined within a gas discharge chamber 132 of a light source. During steady-state operation, the gas discharge chamber 132 is configured to produce a light beam 133 for use by an external or output apparatus 179 (also shown in FIGS. 6 and 7). The output apparatus 179 can be, for example, a photolithography exposure apparatus. The dust collector 100 is positioned along an outflow path 140 that is external to the gas discharge chamber 132, such outflow path 140 extending from the cavity 130 to an active dust trap 145.

Traditionally, the active dust trap 145 is configured to clean components within the cavity 130 of the gas discharge chamber. For example, the active dust trap 145 is configured to remove dust 131 from such components within the cavity 130. In order to do this, the active dust trap 145 receives the dust 131 along with fluid (such as gas) from within the cavity 130 (by way of the outflow path 140) and then traps the dust 131 while permitting the fluid to return to the cavity 130 along a return path 150 that is separate from the outflow path 140. This return fluid that enters the cavity 130 along the return path 150 can be used as a clean fluid (gas) flow to purge components (such as optical elements) of the gas discharge chamber 132. Such optical components in the cavity 130 or at least partly defining the cavity 130 can interact with the light beam 133 or with a precursor light beam that forms the light beam 133. One example of an optical element that can be cleaned is an optical window formed into a wall of the chamber 132, such optical window permitting the light beam 133 (or a precursor light beam) to enter or exit the cavity 130. Purging such components can keep such components clean and prevent build-up of dust on such components. The active dust trap 145 includes, among other possible features, an active element 146 such as an electrostatic precipitator or other non-passive element that traps the dust 131 within the fluid that flows through it.

As the lifetime of gas discharge chambers 132 increases (due to improvements within the manufacturing of the gas discharge chambers 132 and components), the gas discharge chamber 132 produces more dust 131 during operation than the current active dust trap 145 can hold. Over time and usage, the active dust trap 145 can therefore become saturated with dust 131 and then be unable to remove any more dust 131 from the cavity 130 of the chamber 132. In this way, the active dust trap 145 eventually fails to properly return clean fluid to the cavity 130 by way of the return path 150. When this happens, the components within the cavity 130 are not properly cleaned or purged because dust 131 is no longer being removed and the return fluid in the return path 150 is not adequately cleaned. This can then lead to damage of such components and failure of the gas discharge chamber 132 prior to the end of actual lifetime of the gas discharge chamber 132. Moreover, properties of the light beam 133 can be negatively impacted by the damage to the components of the gas discharge chamber 132 and the light beam 133 can become unusable or not up to the requirements for use by the output apparatus 179.

The dust collector 100 is positioned between the cavity 130 of the gas discharge chamber 132 and the active dust trap 145. The dust collector 100 is designed to postpone the saturation of dust 131 within the active dust trap 145. Because of the placement of the dust collector 100 along the outflow path 140, the active dust trap 145 can operate efficiently for the lifetime of the gas discharge chamber 132.

The dust collector 100 includes a collector body 108 that defines an inlet port 102i fluidly communicating with the cavity 130 of the gas discharge chamber 132 and an outlet port 1020 fluidly communicating with the active dust trap 145. The outflow path 140, which is external to the cavity 130 of the gas discharge chamber 132, is defined from the inlet port 102i to the outlet port 1020 along an outflow direction.

The dust collector 100 operates by interrupting the dust-filled fluid flow along the outflow path 140 and forcing the dust-filled fluid flow to turn sharply away from the outflow path 140 and onto a second flow path 142. The flow of the fluid generally is forced to turn sharply back to the outflow path 140 along a third flow path 143 after the dust particles 131 within the fluid have flown out of the fluid due to their own inertia and momentum. In particular, the dust particles 131 have momentum along the direction of the second flow path 142. And, when the fluid is forced to turn back toward the outflow path 140 along the third flow path 143, these particles 131 instead continue along the path of the second flow path 142 without turning back toward the outflow path 140, thus becoming trapped or collected in the collector body 108.

The dust collector 100 includes a baffle 105 extending across the outflow path 140. The baffle 105 is configured (along with the collector body 108) to define the second flow path 142 that extends at least partly along a second direction different from the outflow direction. The second flow path 142 extends to a collection pocket 107 defined in the collector body 108 of the collector 100. The collection pocket 107 is a three-dimensional cavity or space defined within the walls of the collector body 108. In this way, dust particles 131 continue to travel along the second flow path 142 and into the collection pocket 107, where they remain trapped. The baffle 105 has an elongated rounded triangular body 106 that extends from along a baffle direction 105d (FIG. 1C) from a base 111 (FIGS. 1B and 1C). The base 111 aligns with an interior wall 140w of the collector body 108, with the interior wall 140w at least partly defining the outflow path 140 (see FIGS. 1A and 1B). In a local XYZ coordinate system of the baffle 105, the triangular body 106 (specifically, the baffle direction 105d, FIG. 1C) extends along an X direction relative to the base 111, and the base 111 is in a perpendicular plane that includes the Z direction. The Z direction may be a direction that points in the direction of the outflow path 140. (In implementations where the outflow path 140 follows a curved trajectory, the Z direction may be taken as a direction where the outflow path impinges on the baffle 105.) Additionally, the redirected fluid including the dust particles 131 is passively compressed as it traveled along the second flow path 142, and this compression leads to an increase in the velocity of the redirected fluid including the dust particles 131 relative to the velocity of the fluid including the dust particles 131 exiting the cavity 130. For example, the velocity of the redirected fluid including the dust particles 131 can be at least double the velocity of the exhausted fluid, including the dust particles 131, from the cavity 130 into the outflow path 140.

Referring to FIG. 2, an implementation 205 of the baffle 105 is shown in perspective view. The baffle 205 has an elongated rounded roughly triangular body 206 that extends along a baffle direction 205d from a base 211. The base 211 aligns with the interior wall 140w that at least partly defines the outflow path 140 (see FIGS. 1A and 1B). In the local XYZ coordinate system of the baffle 205, the triangular body 206 (specifically, the baffle direction 205d) extends along an X direction relative to the base 211 (which is in the Y-Z plane or is otherwise in a plane that contains the Z direction). The baffle 205 is arranged within the outflow path 140 such that the triangular body 206 extends transversely across the outflow path 140 (see FIGS. 1A and 1B). That is, the baffle direction 205d extends transversely to the direction of the outflow path 140. Thus, in the example of FIGS. 1A-1C, the baffle direction 205d of the triangular body 206 is transverse or roughly perpendicular to the outflow path 140 and the Z direction aligns with the outflow path 140.

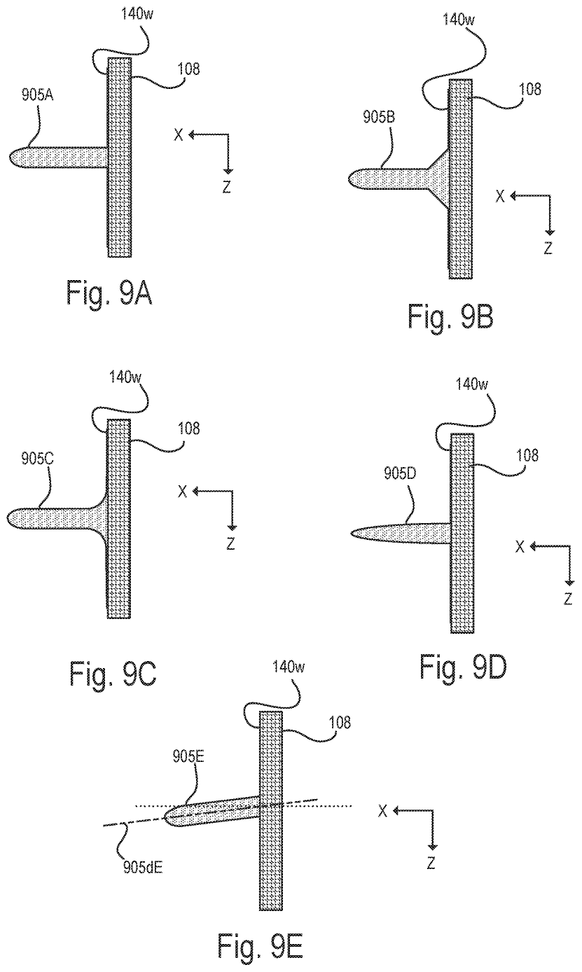

In other implementations, the baffle direction 205d of the triangular body 206 can extend along a direction that is within 5° of the X direction (or the baffle direction 205d), within 10° of the X direction, or within 15° of the X direction while the base 211 remains in the plane of the Y-Z direction. Similarly, the baffle direction 205d of triangular body 206, when fixed within the outflow path 140, may be constructed so that it extends along an angle that is within 5° of perpendicular from the Z direction, within 10° of perpendicular from the Z direction, or within 15° of perpendicular from the Z direction. An example of this implementation is shown in FIG. 9E.

As shown in FIGS. 1A-1C and 2, the baffle 105, 205 (and, in particular, the triangular body 206) lacks any sharp ends or corners that extend into the outflow path 140. This rounded and smooth profile of the triangular body 206 facilitates the flow of the fluid around the triangular body 206 of the baffle 105, 205 while enabling the dust particles 131 to continue along the second flow path 142 to the collection pocket 107. As shown in the close-up of FIG. 1C, a tip 109 of the baffle 105 has a rounded or curved shape along flow paths, that is, along the second flow path 142 and the third flow path 143. If the extent (width) L140 of the outflow path 140 (along the X direction of the baffle 105, see FIG. 1B) is on the order of an inch (such as 1 inch or 0.5 inches or a value between 0.5-1.0 inches), then the tip 109 of the baffle 105 can have a turn or bend radius R105 that is less than 1 inch, less than 0.5 inches, or less than 0.25 inches. Moreover, an extent or length L105 of the baffle 105 (FIG. 1C) along the X direction (or along the direction transverse to the outflow path 140) is at least the length of the extent L140 of the outflow path 140 (FIG. 1B) along the X direction. In the example noted above, if the extent L140 of the outflow path 140 along the X direction is 1 inch, then the length L105 of the baffle 105 is at least 1 inch; or if the extent of the outflow path 140 along the X direction is 0.5 inches, then the length L105 of the baffle 105 is at least 0.5 inches. In various implementations, the baffle 105 may have a length L105 in the X direction of approximately 0.5 inches, 0.8 inches, 1 inch, 1.5 inches, 2 inches, 4 inches, 5 inches, or 6 inches. The baffle 105 may have a length in the Y direction of approximately 0.5 inches, 0.8 inches, 1 inch, 1.5 inches, 2 inches, 4 inches, 5 inches, or 6 inches. The baffle 105 may have a base 211 that has a length in the Z direction of approximately 0.5 inches, 0.8 inches, 1 inch, 1.5 inches, 2 inches, 4 inches, 5 inches, or 6 inches.

The baffle 105, 205 may be a rigid piece and can also be monolithic (made of one primary material). The baffle 105, 205 is made of a material that is non-reactive to the dust particles 131 and the fluid from the cavity 130 of the gas discharge chamber 132. For example, the baffle 105, 205 can be made of a nickel-plated metal, a bare metal, copper, brass, an alloy of nickel and copper, an alloy of copper, or Monel™.

Referring to FIG. 1B, the second flow path 142 is defined within a constricted region 141 that has a constricted cross-sectional area (taken along a direction generally transverse to the flow of fluid along the second flow path 142) relative to the cross-sectional area of the outflow path 140. To put it another way, an extent L142 of the second flow path 142 is smaller than the extent L140 of the outflow path 140. By forcing the dust-filled fluid traveling through the outflow path 140 into the second flow path 142, which has a much smaller cross-sectional area and is angled at a direction distinct from the outflow direction, the fluid speeds up as it traverses the second flow path 142, and the inertia of the dust particles 131 propels those dust particles along the second flow path 142 and toward the collection pocket 107. The fluid can then flow back along the third flow path 143 toward the outflow path 140 and toward the active dust trap 145. A bend flow path 144 is formed adjacent to the tip 109 of the baffle 105 between and connecting the second flow path 142 and the third flow path 143. The flow paths 142, 143, 144 and the outflow path 140 are all openings that permit the fluid to pass. They can have various cross-sectional shapes. For example, the outflow path 140 can have a circular cross-sectional shape (taken along the direction transverse to the direction of fluid flow). Other geometries are also contemplated; for example, the outflow path 140 can have a square, rectangular, or oval cross-sectional shape.

In order to increase the constriction of the second flow path 142, as shown in Fig. 1B, the collector body 108 can include a protrusion 103 that extends toward the tip 109 of the baffle 105. In this case, the constricted region 141 is defined between the protrusion 103 and the elongated body 106/tip 109 of the baffle 105.

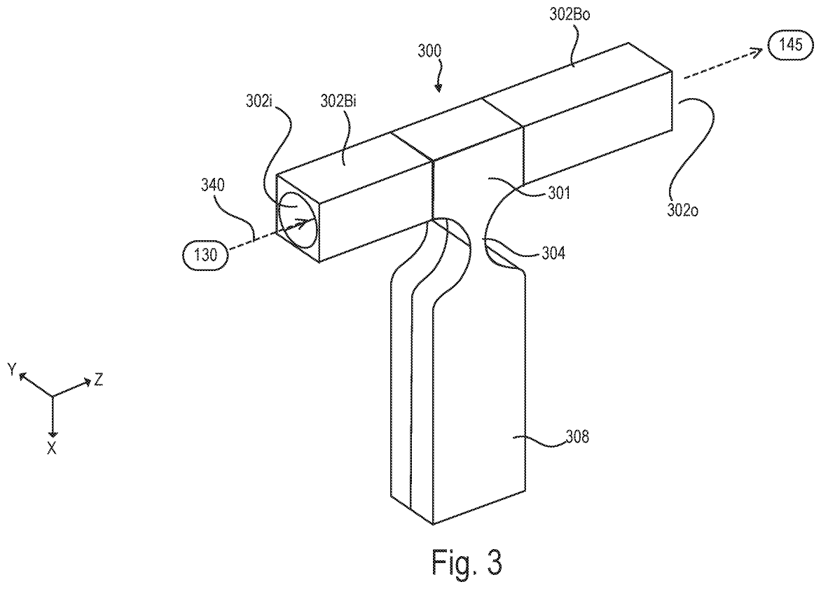

Referring to FIG. 3, an implementation 300 of the dust collector 100 is shown. The dust collector 300 includes a collector body 308 that includes a baffle body 301, a collector body 308, and a neck body 304 between the baffle body 301 and the collector body 308. An outflow path 340 extends through the baffle body 301 and is defined from an inlet port 302i (which is in fluid communication with the cavity 130 of the gas discharge chamber 132) to an outlet port 3020 (which is in fluid communication with the active dust trap 145). The inlet port 302i can be defined within an inlet body 302Bi and the outlet port 3020 can be defined within an outlet body 302Bo. The inlet body 302Bi is physically secured to the gas discharge chamber 132 in order to provide a hermetic seal to prevent leakage of the fluid and dust particles from the inlet port 302i. The outlet body 302Bo is physically secured to the active dust trap 145 in order to provide a hermetic seal to prevent leakage of the fluid (and any dust particles that escape the dust collector 300) from the outlet port 3020. The relative lengths of the inlet body 302Bi and the outlet body 302Bo along the Z direction can be different from what is shown in FIG. 3; for example, the length of the outlet body 302Bo along the Z direction can be shorter than what is shown or it can be on the order of or less than the length of the inlet body 302Bi along the Z direction. The baffle body 301, the neck body 304, and the collector body 308 can be formed as a unitary rigid piece, and can be made of a material that is non-reactive with the fluid and dust particles from the cavity 130 of the gas discharge chamber 132. In some implementations, the baffle body 301, the neck body 304, and the collector body 308 are made of a metal, such as, for example, a nickel-plated metal, a bare metal, copper, brass, an alloy of nickel and copper, an alloy of copper, or Monel.

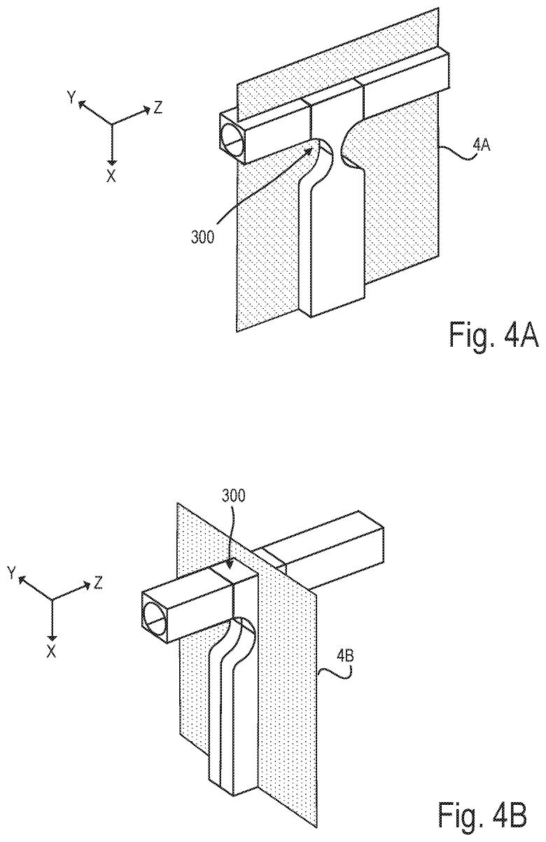

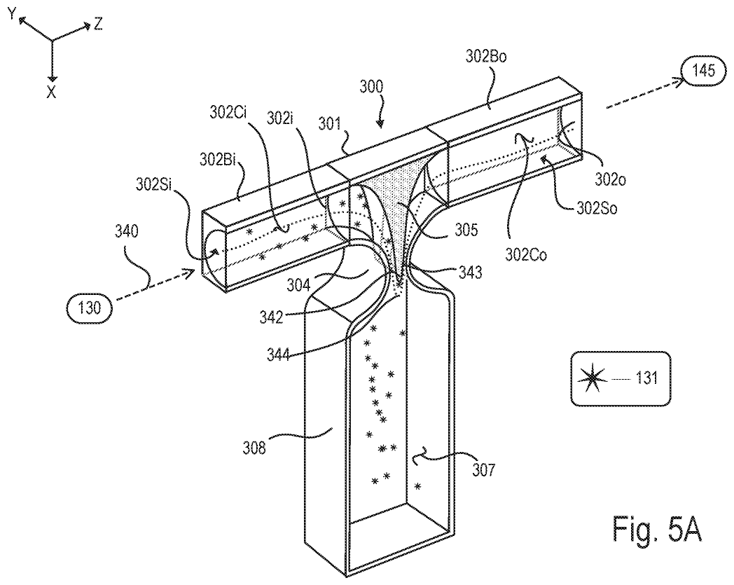

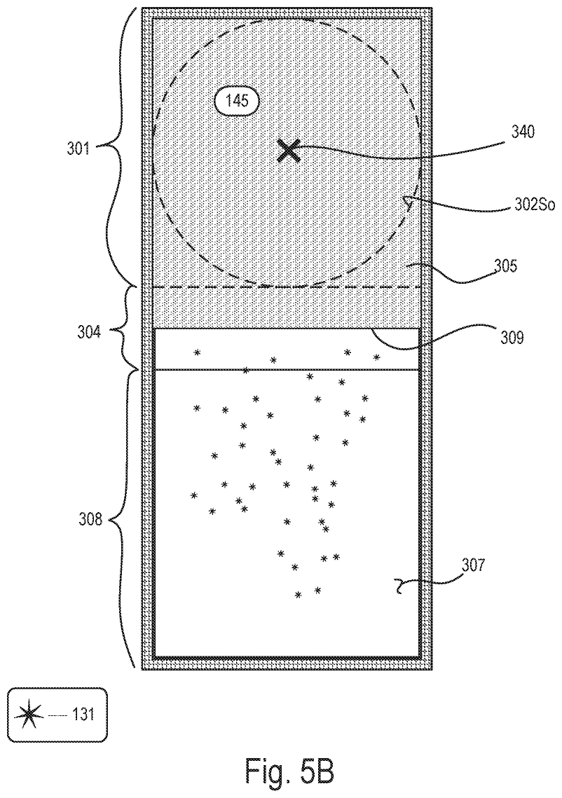

A cross-sectional perspective view taken along XZ plane, as shown in FIG. 4A, is shown in FIG. 5A and a cross-sectional plan view taken along the XY plane, as shown in FIG. 4B, is shown in FIG. 5B. As shown in FIGS. 5A and 5B, the dust collector 300 includes a baffle 305 housed partly within the baffle body 301 and extending into the neck body 304. The inlet port body 302Bi has a cylindrical inner surface 302Si (FIG. 5A) that defines an inlet cavity 302Ci having a round cross section taken along the XY plane; and the outlet port body 302Bo has a cylindrical inner surface 302So that defines an outlet cavity 302Co having a round cross section taken along the XY plane. The collector body 308 defines a collection pocket 307 that receives the flow of the fluid and the dust particles 131 that are redirected from the outflow path 340 onto the second flow path 342 and are pushed between the baffle 305 and the neck body 304 along the second flow path 342. Most of the fluid continues along the bend flow path 344 around the tip 309 (see FIG. 5B) of the baffle 305 and onto the third flow path 343 back toward the outflow path 340 on the way to the active dust trap 145.

Referring to FIG. 6, a dust management apparatus 660 is configured for a cavity 630 of a gas discharge chamber 632 of a light source 665. The light source 665 produces a light beam 666 from a light beam 633 provided by the gas discharge chamber 632. The light beam 666 is provided to an output apparatus 679. The dust management apparatus 660 is configured for removing dust particles 131 from the cavity 630. To this end, the dust management apparatus 660 includes an active dust trap 645, which is an implementation of the active dust trap 145 (FIG. 1A), and a dust collector 600, which is an implementation of the dust collector 100 (FIG. 1A). The dust collector 600 is positioned along an outflow path 640 between the cavity 630 of the gas discharge chamber 632 and the active dust trap 645. The dust management apparatus 660 also includes an exhaust fan 634 within the cavity 630 of the gas discharge chamber 632. The exhaust fan 634 is configured to push the dust particles 131 and the fluid from the cavity 630 to the outflow path 640. The velocity of the dust particles 131 and the fluid from the cavity 630 increases as it flows through the dust collector 600, which can be designed similarly to the dust collectors 100, 300. This increase in velocity occurs as the dust particles 131 and the fluid travel through the second flow path 142, 342, which has the constricted cross-sectional area relative to the cross-sectional area of the outflow path 640. As discussed above, the active dust trap 645 is configured to remove (or avoid accumulation of) dust particles 131 from components within the cavity 630. For example, in some implementations, the cavity 630 can house a pair of electrodes 634a, 634b as well as at least two optical elements 635a, 635b, which can include windows that are transparent to the wavelength of the light beam 633, optical reflectors, and/or output couplers.

During operation of the gas discharge chamber 632, a gain medium contained within the cavity 630 is placed inside an optical resonator (which can be formed from partially-reflective mirrors or even one or more of the windows 635a, 635b). This gain medium is pumped with short (for example, nanosecond) current pulses in a high-voltage electric discharge from an energy source (such as the pair of electrodes 634a, 634b), and this creates a plasma that leads to optical amplification. The light beam 633 (which is an amplified light beam) having a wavelength in the ultraviolet range (for example, deep ultraviolet or DUV range) is produced and output from the gas discharge chamber 632. The gain medium within the cavity 630 is a gas mixture that usually includes a noble gas (such as argon, krypton, or xenon) and a halogen (such as fluorine or chlorine) along with a buffer gas. Thus, for example, the gain medium can include argon and fluorine, krypton and fluorine, or xenon and chlorine. If the gain medium includes argon and fluorine, then the light source 665 may be an argon fluoride (ArF) laser with a wavelength of the amplified light beam 633 about 193 nm. The electrodes 634a, 634b can be made of brass, for example. The fluorine in the gain medium can chemically interact with the material (for example, brass) of the electrodes 634a, 634b, and such interaction can lead to erosion, which can lead to the generation of metal fluoride (or metal chloride if chloride is the halogen) particles. Such particles produced due to erosion are referred to as the dust particles 131 but could alternatively be described simply as particles.

The active dust trap 645 provides a cleaning purge gas along the return path 150, and such cleaning purge gas is configured to push the purge gas along a path relative to the components (such as the windows 635a, 635b and/or the electrodes 634a, 634b) to prevent or reduce the chance of the dust particles 131 coming in contact with such component. For example, the active dust trap 645 can be a metal fluoride trap (MFT), which can use a filter such as a mechanical mesh and an active precipitator that uses electrostatic force to trap dust particles 131 of metal fluoride or other particles. In some implementations, as a portion of the gas discharge gain medium (or fluid) passes through the MFT, metal fluoride dust particles in the contaminated gas discharge gain medium can be adsorbed in the filter within the MFT and any remaining particles can be collected by the electrostatic precipitator. For example, certain MFTs have been previously described in U.S. Pat. No. 6,240,117, issued May 29, 2001 and U.S. Pat. No. 7,819,945, issued Oct. 26, 2010, which are hereby incorporated by reference herein in their entireties.

Nevertheless, even with the active dust trap 645, there are certain circumstances when the dust particles 131 can still recirculate into the cavity 630 through the return path 150 and access (and contaminate) the components of the gas discharge chamber 632. For example, contamination can occur during a gas refill procedure (in which the gain medium is replaced or refilled). As another example, contamination can occur during normal operation of the gas discharge chamber 632 if the active dust trap 645 leaks or is full of the dust particles 131. If a significant number of dust particles 131 deposit on a component within the gas discharge chamber 632, damage can be caused to the component. If the component is an optical element that interacts with the light beam 633 (or a precursor to the light beam 633), then any dust particles 131 on a surface of such optical element can absorb energy from the light beam 633 as well, and this causes the dust particles 131 at the surface of such optical element to heat up, and possibly interact with or become welded to the surface of the optical element. Damage to the surface of an optical element within the cavity 630 can become a critical issue especially with the need to extend the lifetime of the gas discharge chamber 632 and also to increase energy in the light beam 633. The dust management apparatus 660 may help to extend the lifetime of the active dust trap 645 because it redirects dust particles 131 to the dust collector 600, where they become trapped and never reach the active dust trap 645.

Referring to FIG. 7, the light source 665 can be a two-stage light source 765. The light source 765 includes a master oscillator 770A as its first stage and a power amplifier 770B as its second stage. The master oscillator 770A includes a master oscillator gas discharge chamber 732A and the power amplifier 770B includes a power amplifier gas discharge chamber 732B. The master oscillator gas discharge chamber 732A includes as its energy source two elongated electrodes 734Aa, 734Ab that provide a source of pulsed energy to a gain medium 771A within the cavity 730A of the chamber 732A. The power amplifier gas discharge chamber 732B includes as its energy source two elongated electrodes 734Ba, 734Bb that provide a source of pulsed energy to a gain medium 771B within the cavity 730B of the chamber 732B.

The master oscillator 770A provides a pulsed amplified light beam (called a seed light beam) 773 to the power amplifier 770B. The master oscillator gas discharge chamber 732A houses the gain medium 771A in which amplification occurs and the master oscillator 770A includes an optical feedback mechanism such as an optical resonator. The optical resonator is formed between a spectral optical system 774A on one side of the master oscillator gas discharge chamber 732A and an output coupler 775A on a second side of the master oscillator gas discharge chamber 732A. The power amplifier gas discharge chamber 732B houses the gain medium 771B in which amplification occurs when seeded with the seed light beam 773 from the master oscillator 770A. If the power amplifier 770B is designed as a regenerative ring resonator then it is described as a power ring amplifier, and in this case, enough optical feedback can be provided from the ring design. The power amplifier 770B can also include a beam return (such as a reflector) 774B that returns (via reflection, for example) the light beam back into the power amplifier gas discharge chamber 732B to form a circulating and looped path (in which the input into the ring amplifier intersects the output out of the ring amplifier) and also an output coupler 775B for inputting the seed light beam 773 and outputting an amplified light beam 776. The working light beam 766 that is supplied to the output apparatus 779 can correspond to the amplified light beam 776 output from the power amplifier 770B and also additionally modified by other optical components 777 such as beam directing and redirecting and pulse stretching optics.

The gain medium 771A, 771B used in the respective gas discharge chambers 732A, 732B can be a combination of suitable gases for producing the amplified light beam around the required wavelengths, bandwidth, and energy. For example, as discussed above, the gain medium 771A, 771B can include argon fluoride (ArF), which emits light at a wavelength of about 193 nm, or krypton fluoride (KrF), which emits light at a wavelength of about 248 nm.

The gas discharge chambers 732A, 732B include components such as respective windows 735Aa, 735Ab and 735Ba, 735Bb. The windows 735Aa, 735Ab, 735Ba, 735Bb are made of a material that is compatible with the gain media 771A, 771B, respectively. Additionally, the windows 735Aa, 735Ab, 735Ba, 735Bb are made of a material that is able to transmit light that will be produced by the gain media 771A, 771B. Thus, in this example, since the light that is produced is in the DUV range, the windows 735Aa, 735Ab, 735Ba, 735Bb must transmit light having a wavelength in the DUV range. In some implementations, the windows 735Aa, 735Ab, 735Ba, 735Bb are made of a crystalline structure. For example, the windows 735Aa, 735Ab, 735Ba, 735Bb can be made of calcium fluoride, magnesium fluoride, or fused silica.

The light source 765 can also include a controller 778 that is configured to control operation of the light source 765 and can communicate with the output apparatus 779.

One or more of the gas discharge chambers 732A, 732B can be configured with a respective dust management apparatus 760A, 760B, respectively. Each dust management apparatus 760A, 760B is designed similarly to the dust management apparatus 660 of FIG. 6. Thus, each dust management apparatus 760A, 760B includes a respective active dust trap 745A, 745B communicating with the respective cavity 730A, 730B by way of the respective outflow path 740A, 740B external to the cavity 730A, 730B and a respective dust collector 700A, 700B. The dust collector 700A, 700B is along the outflow path 740A, 740B between the respective active dust trap 745A, 745B and the respective chamber 730A, 730B. The dust collector 700A, 700B is designed like the dust collector 100, 300, or 600 and the active dust trap 745A, 745B is designed like the active dust trap 145, 645.

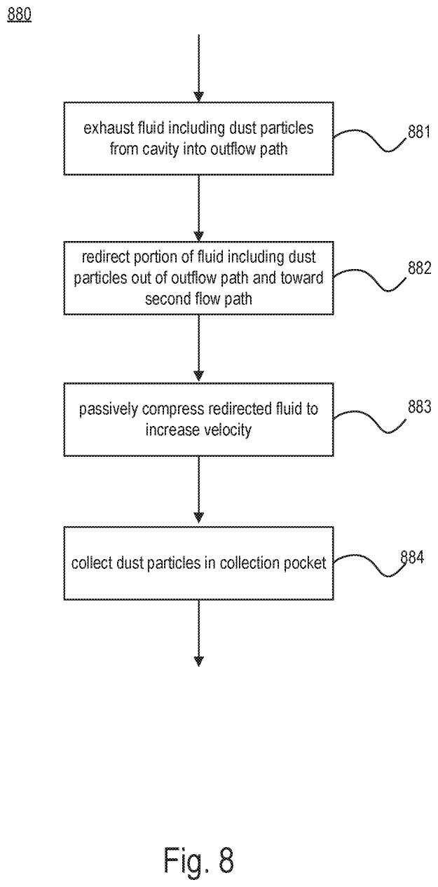

Referring to FIG. 8, a procedure 880 is performed to collect and remove the dust particles 131 from the cavity 130 (or any of the cavities 630, 730A, 730B). Reference is made to the dust collector 100 of FIG. 1A when discussing the procedure 880 but the procedure 880 can be performed by the dust collector 300, 700A, or 700B. The procedure 880 includes exhausting fluid including dust particles 131 from the cavity 130 into the outflow path 140 external to the cavity 130 toward the active dust trap 145 (881). At least a portion of the fluid including the dust particles 131 is redirected out of the outflow path 140 and toward a second flow path 142 that extends at least partly along a second direction that is different from a direction of the outflow path 140 (882). The redirected fluid, including the dust particles 131, is passively compressed to thereby increase the velocity of the redirected fluid including the dust particles 131 (883). And, the dust particles 131 are collected in the collection pocket 107 while permitting the redirected fluid to return to the outflow path 140 on the way to the active dust trap 145 (884). With reference to FIG. 6, the fluid including the dust particles 131 can be exhausted from the cavity 630 (881) by operating the exhaust fan 634 within the cavity 630, the exhaust fan 634 configured to push the dust 131 and the fluid from the cavity 630 to the outflow path 640.

Referring again to FIG. 7, the output apparatus 779 can correspond to a photolithography exposure apparatus or scanner, which is a machine that applies a desired pattern onto a target portion of a substrate S (such as a silicon wafer). The light beam 766 (which can have a wavelength in the deep ultraviolet (DUV) range) interacts with a projection optical system PS, which projects the DUV light beam 766 through a mask MA onto the photoresist of the wafer S. In this way, one or more layers of chip design is patterned onto the photoresist and the wafer S is subsequently etched and cleaned. The photolithography exposure apparatus 779 relies on a stable light source 765 to ensure accurate and error-free fabrication of nanoscale integrated circuits using the wafer S. Stable illumination intensity in the light beam 766 permits predictable dosing of illumination on the photoresist of the wafer S. On the other hand, unstable illumination in the light beam 766 can cause the photoresist to not fully develop, and this can cause printing errors. The dust particles 131 (FIG. 1A) within either of the gas discharge chambers 732A, 732B can adversely impact the intensity of the light beam 766, causing errors in dosages at the wafer S. The dust collectors 700A, 700B and the dust management apparatuses 760A, 760B reduce the amount of dust particles 131 within the respective gas discharge chambers 732A, 732B by expanding the life of the active dust trap 745A, 745B.

Other implementations, such as described below, are within the scope of the claims.

For example, the baffle 105 can have a shape different from that shown in FIGS. 1A-1C or the implementation 205 of FIG. 2. For example, other implementations 905A, 905B, 905C, 905D of the baffle 105/205 are shown in FIGS. 9A, 9B, 9C, and 9D, respectively, when mounted to the interior wall 140w of the collector body 108. As mentioned above, in other implementations, the baffle direction 205d of the triangular body 206 can extend along a direction that is within 5° of the X direction, within 10° of the X direction, or within 15° of the X direction while the base 211 remains in a plane of the that includes the Z direction. FIG. 9E shows an implementation in which a baffle direction 905dE is orientated at an angle that is about 7° away from the X direction.

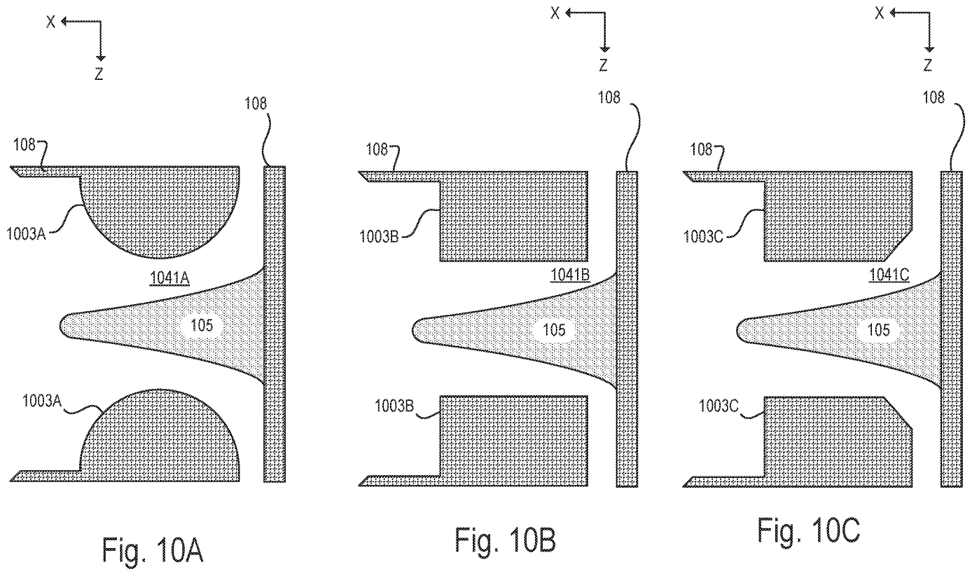

Referring to FIGS. 10A-10C, in other implementations, the protrusion 103 of the collector body 108 can have a geometry that is different from that shown in FIGS. 1A and 1B. For example, a rounded or circular implementation 1003A of the protrusion 103 is shown in FIG. 10A; an implementation 1003B of the protrusion 103 with a rectangular cross section is shown in FIG. 10B; and an implementation 1003C of the protrusion 103 with a beveled edge is shown in FIG. 10C. In all cases, in order to increase the constriction of the second flow path 142, protrusion 1003A, 1003B, 1003C extends toward a body or sidewall of the baffle 105 and forms the constricted region 1041A, 1041B, 1041C, respectively. Although FIGS. 10A-10C depict examples with symmetric structures of the protrusion 103, other arrangements are also contemplated. For example, a protrusion 1003A with a circular structure may be deployed on an inlet side of the collector body 108, while a protrusion 1003B with a rectangular structure may be deployed on an outlet side of the collector body 108.

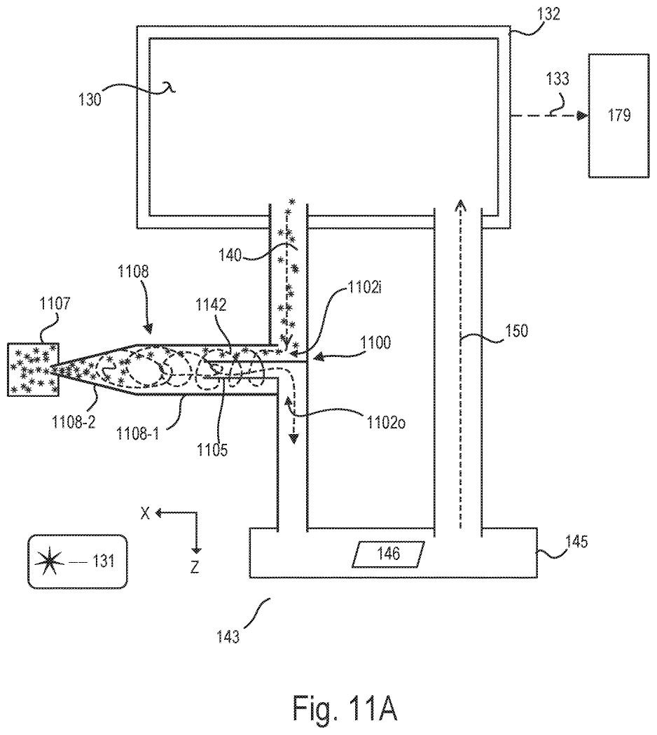

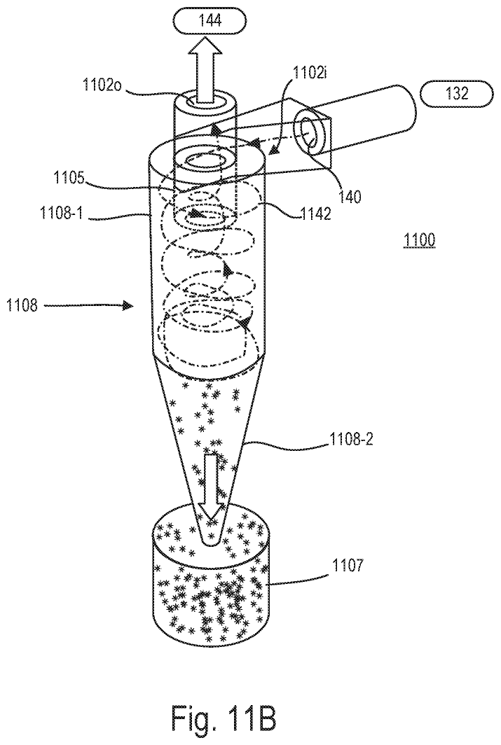

Referring to FIGS. 11A and 11B, an implementation 1100 of the dust collector 100 includes a collector body 1108 that designed as a spiral trap arranged at a tangential angle relative to the outflow path 1140. The dust collector 1100 defines an inlet port 1102i and an outlet port 11020. The collector body 1108 includes a cylindrical portion 1108-1, a conical portion 1108-2 extending from the cylindrical portion 1108-1, and a collection pocket 1107. The conical portion 1108-2 is fluidly coupled to a collection pocket 1107 that collects the dust particles 131. A central cylinder 1105 extends through the cylindrical portion 1108-1.

At the inlet port 1102i, the central cylinder 1105 in combination with the inner wall of the cylindrical portion 1108-1 interrupt the fluid flow along the outflow path 1140 and cause the fluid to spiral around the central cylinder 1105 along a second flow path 1142 and toward the conical portion 1108-2. The dust particles 131 have momentum and continue along the spiraling path into the conical portion 1108-2 where they are trapped in the collection pocket 1107, while the fluid (represented by the dashed line) bounces off the interior wall of the conical portion 1108-2 and exits from an interior passage of the central cylinder 1105 through the outflow port 11020 toward the active dust trap 145.

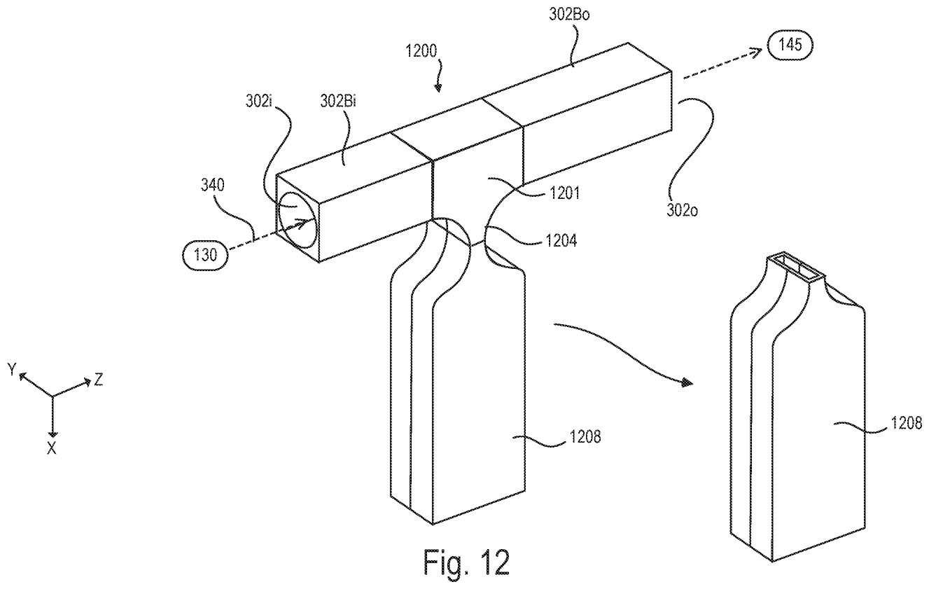

Referring to FIG. 12, in other implementations 1200 of the dust collector 100, the collector body 1208 is detachable from other portions of the dust collector 1200. Specifically, the collector body 1208 can detach from a main body 1201 (which can be similar to the baffle body 301) at a neck region 1204. In this way, the collector body 1208 (where the dust particles 131 are trapped) can be replaced with a new collector body 1208 that is empty or it can be emptied of the dust particles 131, cleaned, and replaced.

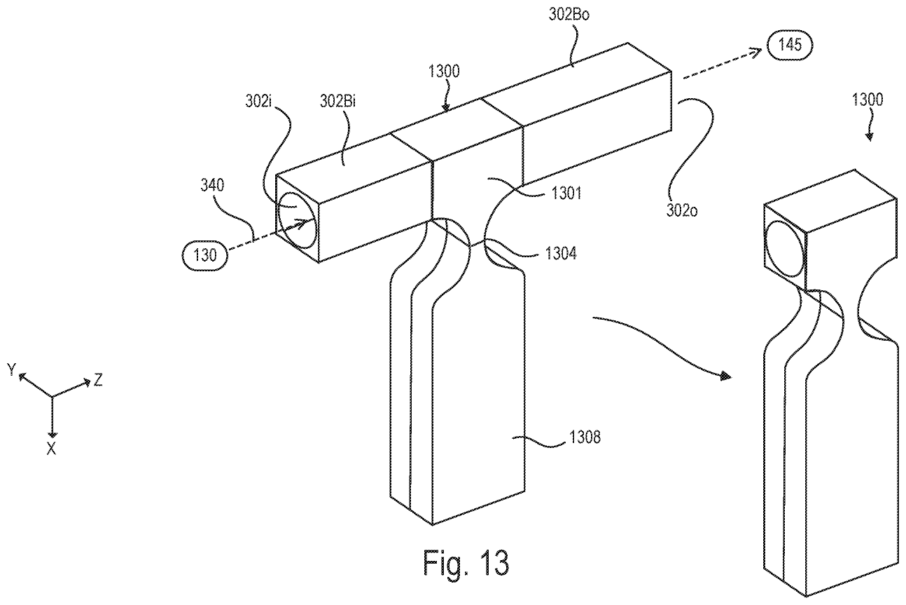

Referring to FIG. 13, in still other implementations 1300 of the dust collector 100, the entire dust collector 1300 (including the collector body 1308, the main body 1301, and the neck region 1304) can be removed from the outflow path 340.

In both dust collector 1200 and dust collector 1300, the section that is replaceable can be separated from the rest of the dust collector or the outflow path 340 using any suitable fluid mechanism such as a valves or cut-off valve. In particular, the mechanism that enables the detachment is configured to ensure that the trapped dust does not re-enter the outflow path 340. For example, a separate seal or blocking mechanism can be placed or activated between the main body 1301 and the collector body 1308 before disconnecting the main body 1301 from the outflow path 340 (to prevent the dust particles 131 or air within the collector body 1308 from re-entering the outflow path 340). The seal/blocking mechanism can be activated within the neck region 1304.

These replaceable designs enable the dust collector 1200, 1300 to be replaceable during the entire lifetime of the chamber 132.

The implementations can be further described using the following clauses.
1. A dust collector for a gas discharge chamber of a light source, the dust collector comprising:
an inlet port fluidly communicating with a cavity of the gas discharge chamber;
an outlet port fluidly communicating with an active dust trap such that an outflow path external to the cavity of the gas discharge chamber is defined from the inlet port to the outlet port along an outflow direction; and
a passive dust trap extending across the outflow path and configured to define a second flow path that extends at least partly along a second direction different from the outflow direction and to a collection pocket defined in a collector body of the passive dust trap.
2. The dust collector of clause 1, wherein the passive dust trap comprises a baffle.
3. The dust collector of clause 2, wherein the baffle extends transversely across the outflow path.
4. The dust collector of clause 2, wherein the second flow path has a constricted cross-sectional area relative to a cross-sectional area of the outflow path.
5. The dust collector of clause 2, wherein the baffle extends along an angle that is between 75°-105° or between 85°-95° relative to the outflow direction.
6. The dust collector of clause 2, wherein the baffle also defines a third flow path that extends from the second flow path and toward the outflow path on the way to the active dust trap such that a bend flow path extends between the second flow path and the third flow path around the baffle.
7. The dust collector of clause 2, wherein the collector body includes a protrusion that extends toward a tip of the baffle such that a constricted region of the second flow path is defined between the protrusion and the baffle near the baffle tip.
8. The dust collector of clause 7, wherein the constricted region has a cross-sectional area that is smaller than a cross-sectional area of the outflow path.
9. The dust collector of clause 2, wherein the baffle lacks sharp ends and lacks sharp corners.
10. The dust collector of clause 2, wherein a profile of the baffle along the flow paths is smooth.
11. The dust collector of clause 2, wherein a tip of the baffle has a curved shape that has a turn radius that is less than one inch, less than 0.5 inches, or less than 0.25 inches.
12. The dust collector of clause 2, wherein the baffle extends across the outflow path along a transverse plane and an extent of the baffle along a transverse direction is greater than or equal to an extent of the outflow path.
13. The dust collector of clause 2, wherein the baffle is rigid.
14. The dust collector of clause 2, wherein the baffle made of a nickel-plated metal, a bare metal, copper, brass, an alloy of nickel and copper, an alloy of copper, or Monel.
15. The dust collector of clause 1, wherein the passive dust trap is configured to trap dust particles within the collection pocket.
16. The dust collector of clause 1, wherein an interior of the collector body defines a cylindrical region and a conically-shaped region, wherein the second flow path forms a spiraling shape that extends through the cylindrical region, the conically-shaped region, and to the collection pocket.
17. The dust collector of clause 16, wherein the flow of the spiraling shape extends from the collection pocket and back toward the outflow path along a third flow path such that a spiral flow path extends between the second flow path and the third flow path.
18. The dust collector of clause 1, wherein the collector body is detachable from the other portions of the passive dust trap.
19. The dust collector of clause 1, wherein the passive dust trap is detachable from the outflow path.
20. A dust collector for a gas discharge chamber of a light source, the dust collector comprising:
an inlet port fluidly communicating with a cavity of the gas discharge chamber;
an outlet port fluidly communicating with an active dust trap such that an outflow path external to the cavity of the gas discharge chamber is defined from the inlet port to the outlet port along an outflow direction; and
a collector along the outflow path, the collector including a collector body defining a second flow path extending from the outflow path to a collection pocket, the second flow path extending along a second direction that is different from the outflow direction.
21. The dust collector of clause 20, wherein the second flow path is configured to trap dust particles within the collection pocket.
22. The dust collector of clause 20, wherein the second flow path at least partly extends along an angle that is between 75°-105° or between 85°-95° relative to the outflow direction.
23. The dust collector of clause 20, wherein the collector body further defines a third flow path that extends from the second flow path around a bend and toward the outflow path on the way to the active dust trap.
24. The dust collector of clause 20, wherein the second flow path extends within a defined structure that lacks sharp ends or corners.
25. The dust collector of clause 20, wherein the second flow path is defined between a baffle extending transversely across the outflow path and a protrusion of the collector body that extends toward a tip of the baffle.
26. The dust collector of clause 25, wherein the collector body further defines a third flow path that extends from the second flow path toward the outflow path and the active dust trap such that a bend flow path extends at least partly around the tip of the baffle about a turn radius that is less than one inch, less than 0.5 inches, or less than 0.25 inches.
27. The dust collector of clause 20, wherein the second flow path has a constricted cross-sectional area relative to a cross-sectional area of the outflow path.
28. The dust collector of clause 20, wherein the second flow path extends to a cylindrical region and a conically-shaped region defined in the collector body between the outflow path and the collection pocket, and forms a cyclone that extends to the collection pocket.
29. The dust collector of clause 28, wherein the flow of the cyclone extends from the collection pocket and back toward the outflow path along a third flow path such that a cyclone flow path extends between the second flow path and the third flow path.
30. The dust collector of clause 20, wherein the collector is detachable from the outflow path.
31. A dust management apparatus for a gas discharge chamber of a light source, the dust management apparatus comprising:
an active dust trap fluidly communicating with a cavity of the gas discharge chamber by way of an outflow path external to the cavity of the gas discharge chamber; and
a dust collector along the outflow path between the active dust trap and the gas discharge chamber cavity, the dust collector including a baffle extending across the outflow path and configured to define a second flow path that extends at least partly along a second direction different from the outflow direction and to a collection pocket defined in a collector body.
32. The dust management apparatus of clause 31, further comprising an exhaust fan within the cavity of the gas discharge chamber, the exhaust fan configured to direct dust and fluid from the cavity of the gas discharge chamber to the outflow path.
33. The dust management apparatus of clause 32, wherein a velocity of the flow of the dust and fluid through the outflow path increases as it travels through the dust collector.
34. The dust management apparatus of clause 31, wherein the baffle extends transversely across the outflow path.
35. The dust management apparatus of clause 31, wherein the baffle is configured to cause dust particles to become trapped within the collection pocket.
36. The dust management apparatus of clause 31, wherein the second flow path has a constricted cross-sectional area relative to a cross-sectional area of the outflow path.
37. The dust management apparatus of clause 31, wherein the collector body includes a protrusion that extends toward a tip of the baffle such that a constricted region of the second flow path is defined between the protrusion and the baffle near the baffle tip.
38. The dust management apparatus of clause 31, wherein the baffle lacks sharp ends or corners.
39. The dust management apparatus of clause 31, wherein a surface profile of the baffle has a smooth shape.
40. The dust management apparatus of clause 31, wherein the baffle extends across the outflow path along a transverse plane and an extent of the baffle along a transverse direction is greater than or equal to an extent of the outflow path.
41. A method of collecting dust from a cavity of a gas discharge chamber of a light source, the method comprising:
exhausting fluid including dust particles from the cavity into an outflow path external to the cavity toward an active dust trap;
redirecting at least a portion of the fluid including the dust particles out of the outflow path and toward a second flow path that extends at least partly along a second direction that is different than a direction of the outflow path;
passively compressing the redirected fluid including the dust particles to thereby increase the velocity of the redirected fluid including the dust particles; and
collecting dust particles in a collection pocket while permitting the redirected fluid to return to the outflow path on the way to the active dust trap.
42. The method of clause 41, wherein exhausting fluid including dust particles from the cavity comprises operating an exhaust fan within the cavity of the gas discharge chamber, the exhaust fan configured to direct dust and fluid from the cavity of the gas discharge chamber to the outflow path.
43. The method of clause 41, wherein redirecting at least the portion of the fluid out of the outflow path and toward the second flow path comprises blocking the fluid from directly traveling toward the active dust trap with a baffle that extends across the outflow path and defines the second flow path.
44. The method of clause 41, wherein passively compressing the redirected fluid comprises pushing the redirected fluid through a constricted region of the second flow path, the constricted region defined between a baffle extending across the outflow path and a protrusion of a collector body that defines the collection pocket.
45. The method of clause 41, wherein increasing the velocity of the redirected fluid comprises increasing the velocity of the redirected fluid to be at least double the velocity of the exhausted fluid from the cavity into the outflow path.

The above-described implementations and other implementations are within the scope of the following claims.

1. A dust collector for a gas discharge chamber of a light source, the dust collector comprising:
an inlet port fluidly communicating with a cavity of the gas discharge chamber;
an outlet port fluidly communicating with an active dust trap such that an outflow path external to the cavity of the gas discharge chamber is defined from the inlet port to the outlet port along an outflow direction; and
a passive dust trap extending across the outflow path and configured to define a second flow path that extends at least partly along a second direction different from the outflow direction and to a collection pocket defined in a collector body of the passive dust trap.

2. The dust collector of claim 1, wherein the passive dust trap comprises a baffle that extends transversely across the outflow path.

3. The dust collector of claim 1, wherein an interior of the collector body defines a cylindrical region and a conically-shaped region, wherein the second flow path forms a spiraling shape that extends through the cylindrical region, the conically-shaped region, and to the collection pocket.

4. The dust collector of claim 3, wherein the flow of the spiraling shape extends from the collection pocket and back toward the outflow path along a third flow path such that a spiral flow path extends between the second flow path and the third flow path.

5. The dust collector of claim 1, wherein the collector body is detachable from the other portions of the passive dust trap.

6. The dust collector of claim 1, wherein the passive dust trap is detachable from the outflow path.

7. A dust collector for a gas discharge chamber of a light source, the dust collector comprising:
an inlet port fluidly communicating with a cavity of the gas discharge chamber;
an outlet port fluidly communicating with an active dust trap such that an outflow path external to the cavity of the gas discharge chamber is defined from the inlet port to the outlet port along an outflow direction; and
a collector along the outflow path, the collector including a collector body defining a second flow path extending from the outflow path to a collection pocket, the second flow path extending along a second direction that is different from the outflow direction.

8. The dust collector of claim 7, wherein the second flow path is configured to trap dust particles within the collection pocket.

9. The dust collector of claim 7, wherein the second flow path at least partly extends along an angle that is between 75°-105° or between 85°-95° relative to the outflow direction.

10. The dust collector of claim 7, wherein the collector body further defines a third flow path that extends from the second flow path around a bend and toward the outflow path on the way to the active dust trap.

11. The dust collector of claim 7, wherein the second flow path extends within a defined structure that lacks sharp ends or corners.

12. The dust collector of claim 7, wherein the second flow path is defined between a baffle extending transversely across the outflow path and a protrusion of the collector body that extends toward a tip of the baffle.

13. The dust collector of claim 12, wherein the collector body further defines a third flow path that extends from the second flow path toward the outflow path and the active dust trap such that a bend flow path extends at least partly around the tip of the baffle about a turn radius that is less than one inch, less than 0.5 inches, or less than 0.25 inches.

14. The dust collector of claim 7, wherein the second flow path has a constricted cross-sectional area relative to a cross-sectional area of the outflow path.

15. The dust collector of claim 7, wherein the second flow path extends to a cylindrical region and a conically-shaped region defined in the collector body between the outflow path and the collection pocket, and forms a cyclone that extends to the collection pocket.

16. The dust collector of claim 15, wherein the flow of the cyclone extends from the collection pocket and back toward the outflow path along a third flow path such that a cyclone flow path extends between the second flow path and the third flow path.

17. The dust collector of claim 7, wherein the collector is detachable from the outflow path.

18. A method of collecting dust from a cavity of a gas discharge chamber of a light source, the method comprising:
exhausting fluid including dust particles from the cavity into an outflow path external to the cavity toward an active dust trap;
redirecting at least a portion of the fluid including the dust particles out of the outflow path and toward a second flow path that extends at least partly along a second direction that is different than a direction of the outflow path;
passively compressing the redirected fluid including the dust particles to thereby increase the velocity of the redirected fluid including the dust particles; and
collecting dust particles in a collection pocket while permitting the redirected fluid to return to the outflow path on the way to the active dust trap.

19. The method of claim 18, wherein exhausting fluid including dust particles from the cavity comprises operating an exhaust fan within the cavity of the gas discharge chamber, the exhaust fan configured to direct dust and fluid from the cavity of the gas discharge chamber to the outflow path.

20. The method of claim 18, wherein redirecting at least the portion of the fluid out of the outflow path and toward the second flow path comprises blocking the fluid from directly traveling toward the active dust trap with a baffle that extends across the outflow path and defines the second flow path.

21. The method of claim 18, wherein passively compressing the redirected fluid comprises pushing the redirected fluid through a constricted region of the second flow path, the constricted region defined between a baffle extending across the outflow path and a protrusion of a collector body that defines the collection pocket.

22. The method of claim 18, wherein increasing the velocity of the redirected fluid comprises increasing the velocity of the redirected fluid to be at least double the velocity of the exhausted fluid from the cavity into the outflow path.
